(19) United States
(12) Patent Application Publication
(10) Pub. No.: US 2014/0239366 A1
(43) Pub. Date: Aug. 28, 2014

(54) NON-VOLATILE SEMICONDUCTOR STORAGE DEVICE

(71) Applicant: KABUSHIKI KAISHA TOSHIBA, Tokyo (JP)

(72) Inventors: Takashi IZUMIDA, Yokohama-Shi (JP); Masaki KONDO, Yokkaichi-Shi (JP); Hiroshi AKAHORI, Yokkaichi-Shi (JP); Nobutoshi AOKI, Yokohama-Shi (JP)

(73) Assignee: KABUSHIKI KAISHA TOSHIBA, Tokyo (JP)

(21) Appl. No.: 14/187,131

(22) Filed: Feb. 21, 2014

(30) Foreign Application Priority Data
Feb. 26, 2013 (JP) 2013-035909

(51) Int. Cl. H01L 27/115

(52) U.S. Cl. CPC H01L 27/11517
USPC 257/316

(57) ABSTRACT

According to an embodiment, a non-volatile semiconductor storage device includes a silicon substrate including an active region isolated by an element isolation insulating film, a first insulating film formed on the active region, a charge accumulation layer formed on the first insulating film, a second insulating film formed on the charge accumulation layer, and a control gate formed on the second insulating film. A plane of the active region being in contact with the element isolation insulating film is a (100) plane or a plane inclining from the (100) plane by an inclination angle of 5° or less.

### CROSS REFERENCE TO RELATED APPLICATION

This application is based upon and claims the benefit of priority from the prior Japanese Patent Application No. 2013-035909 filed on Feb. 26, 2013 in Japan, the entire contents of which are incorporated herein by reference.

### FIELD

Embodiments described herein relate generally to a non-volatile semiconductor storage device.

### BACKGROUND

In a NAND-type flash memory, a memory cell array is configured such that a NAND string made of a plurality of memory cells connected in series is arrayed, and the NAND-type flash memory is suitable for realizing a large capacity. Further, enhancement of the large capacity by a multi-value storage method in which data having two bits or more is stored in one memory cell has been proposed.

In writing data in the NAND-type flash memory, a writing operation (program operation) and a following verification operation are repeated while a writing voltage is increased (step-up operation is performed) until a desired threshold voltage can be obtained.

With miniaturization of a cell, a neutral threshold voltage of a memory cell is decreased due to influence of a fixed charge of an interface between a semiconductor layer below a floating gate and an element isolation insulating film of an STI structure. Here, the “neutral threshold voltage” refers to a threshold voltage in a state in which an electric charge is not stored in the floating gate. Due to the decrease in the neutral threshold voltage, an electric charge amount necessary for writing is increased, an electric field applied to a tunnel insulating film at retention of an electric charge is increased, a tunnel probability is increased, and the retention characteristic of data is deteriorated.

### BRIEF DESCRIPTION OF THE DRAWINGS

FIG. 1 is a view illustrating a memory core configuration of a non-volatile semiconductor storage device according to a first embodiment.

FIG. 2 is a view illustrating an example of a method of writing data according to the first embodiment.

FIG. 3 is a view illustrating another example of the method of writing data according to the first embodiment.

FIG. 4 is a plan view schematically illustrating a structure of the non-volatile semiconductor storage device of FIG. 1.

FIG. 5 is a vertical sectional view of the non-volatile semiconductor storage device according to the first embodiment.

FIG. 6 is a vertical sectional view of the non-volatile semiconductor storage device according to the first embodiment.

FIG. 7A is a view illustrating a crystal structure of silicon.

FIG. 7B is a view illustrating a (100) plane of the silicon.

FIG. 7C is a view illustrating a (110) plane of the silicon.

FIG. 8 is a vertical sectional view of a non-volatile semiconductor storage device according to a second embodiment.

FIG. 9 is a vertical sectional view of another non-volatile semiconductor storage device according to the second embodiment.

FIG. 10A is a vertical sectional view of still another non-volatile semiconductor storage device according to the second embodiment.

FIG. 10B is a vertical sectional view of still another non-volatile semiconductor storage device according to the second embodiment.

FIG. 11A is a top view illustrating an active region of a non-volatile semiconductor storage device according to a third embodiment.

FIG. 11B is a top view illustrating the active region of another non-volatile semiconductor storage device according to the third embodiment.

FIG. 11C is a top view illustrating the active region of still another non-volatile semiconductor storage device according to the third Embodiment.

FIG. 12 is a vertical sectional view of a non-volatile semiconductor storage device according to a fourth embodiment.

FIG. 13 is a vertical sectional view of a non-volatile semiconductor storage device according to a fifth embodiment.

FIG. 14 is a vertical sectional view of another non-volatile semiconductor storage device according to the fifth embodiment.

### DETAILED DESCRIPTION

According to an embodiment, a non-volatile semiconductor storage device includes a silicon substrate including an active region isolated by an element isolation insulating film, a first insulating film formed on the active region, a charge accumulation layer formed on the first insulating film, a second insulating film formed on the charge accumulation layer, and a control gate formed on the second insulating film. A plane of the active region being in contact with the element isolation insulating film is a (100) plane or a plane inclining from the (100) plane by an inclination angle of 5° or less.

Hereinafter, embodiments of the present invention will be described with reference to the drawings.

### First Embodiment

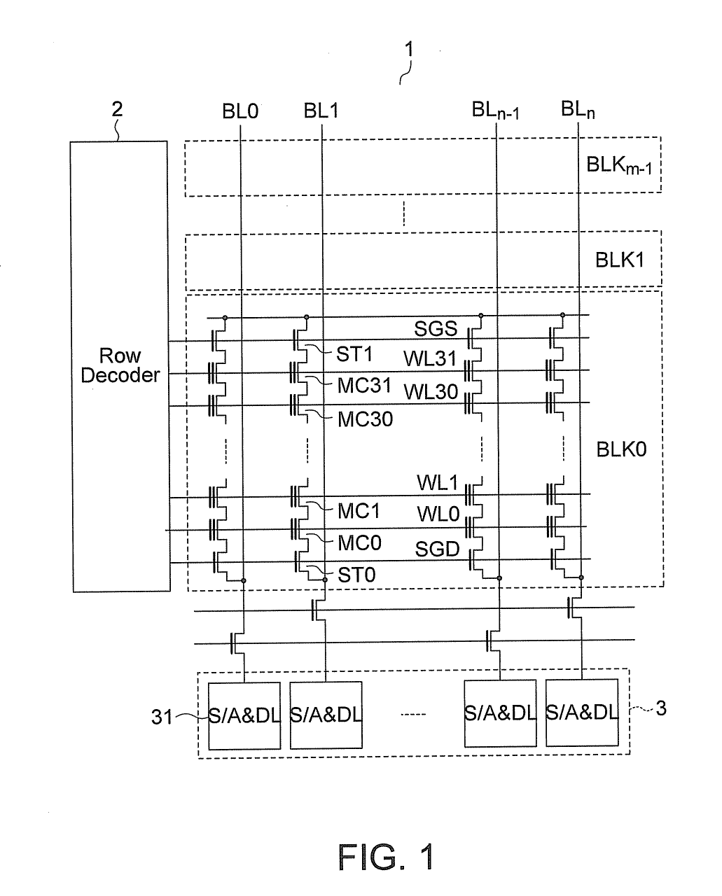

FIG. 1 illustrates a memory core configuration of a non-volatile semiconductor storage device (NAND-type flash memory) according to a first embodiment. In a memory cell array 1, a plurality of NAND strings in which electrically rewritable non-volatile memory cells MC0 to MC31 are connected in series is arranged.

One end of each NAND string is connected to a bit line BL through a selection transistor ST0, and the other end is connected to a source line SL through a selection transistor ST1. Control gates of the memory cells MC0 to MC31 in the NAND string are connected to different word lines WL0 to WL31. Gates of the selection transistors ST0 and ST1 are connected to selection gate lines SGD and SGS extending in parallel with the word lines.

A row decoder 2 selects and drives the word lines WL and the selection gate lines SGD and SGS. Each bit line BL is connected to a sense amplifier and data latch 31 in a sense amplifier circuit 3.

In FIG. 1, the bit line BL is connected with the sense amplifier and data latch 31 in one-to-one correspondence. In this case, the memory cells selected by one word line WL serve as one page to be subjected to simultaneous writing/reading.

Two adjacent bit lines BL may be configured to share one sense amplifier and data latch 31. In this case, half of the memory cells selected by one word line WL serve as one page to be subjected to simultaneous writing/reading.

A group of NAND strings that share a word line configures a block that is a unit of data erasing. As illustrated in FIG. 1, a plurality of blocks BLK0, BLK1, . . . BLKm−1 is arrayed in a direction of the bit line BL.

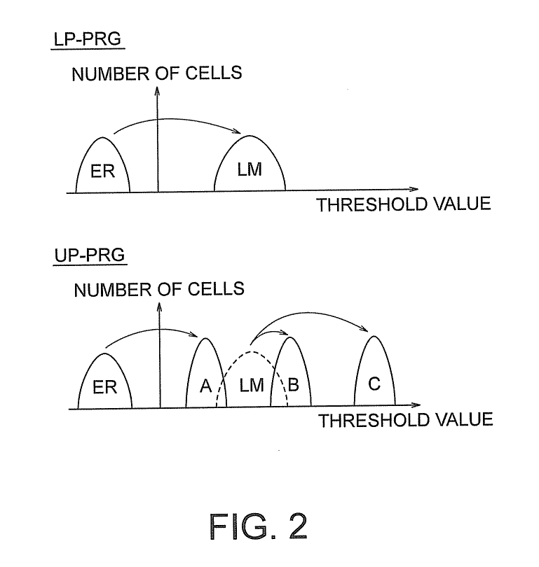

FIG. 2 is an example of a method of writing data according to the present embodiment. In this example, a 4-value data storage method is executed in a non-volatile semiconductor storage device.

4-value data is defined by a data state (erasing state) ER that is a negative threshold voltage, and data states A, B, and C that are positive threshold voltages. Hereinafter, the data state defined by a threshold voltage may be referred to as a threshold level or a level.

To write the 4-value data, first, all of the memory cells in a selection block are set to the negative threshold voltage level ER. This is the data erasing. The data erasing is performed such that a positive erasing voltage is provided to a well region in which a cell array is formed, all of the word lines of the selection block is set to 0 V, and electrons of floating gates (charge accumulation layers) of all of the memory cells are released.

Next, a lower page writing (lower page program) in which a part of the memory cells in the level ER is written up to a middle level LM of the levels A and B is performed. Following that, upper page writing (upper page program) in which a threshold voltage is increased from the level ER to the level A, and from the middle level LM to the levels B and C is performed.

The above data writing is performed as operations of providing a selection word line with a writing voltage, providing a non-selection word line with a writing pass voltage, providing a bit line with a Vss (in a case of “0” writing that increases the threshold voltage) or a Vdd (in a case of prohibiting writing that does not increase the threshold voltage), and selectively injecting an electron to a floating gate of a memory cell.

That is, in the case of “0” writing, when the Vss provided to the bit line is transferred to a channel of the selection cell of the NAND string, and the writing voltage is provided, an electron is injected from the channel to the floating gate by a tunnel current. In the case of “1” writing (prohibiting writing), a NAND cell channel is charged to the threshold voltage of the selection transistor to float, and when a writing voltage is provided, a channel of the memory cell is boosted by capacity coupling with the control gate, and the electron injection is not caused.

For data writing, usually, a step-up writing method of gradually increasing a writing voltage in each writing cycle is used.

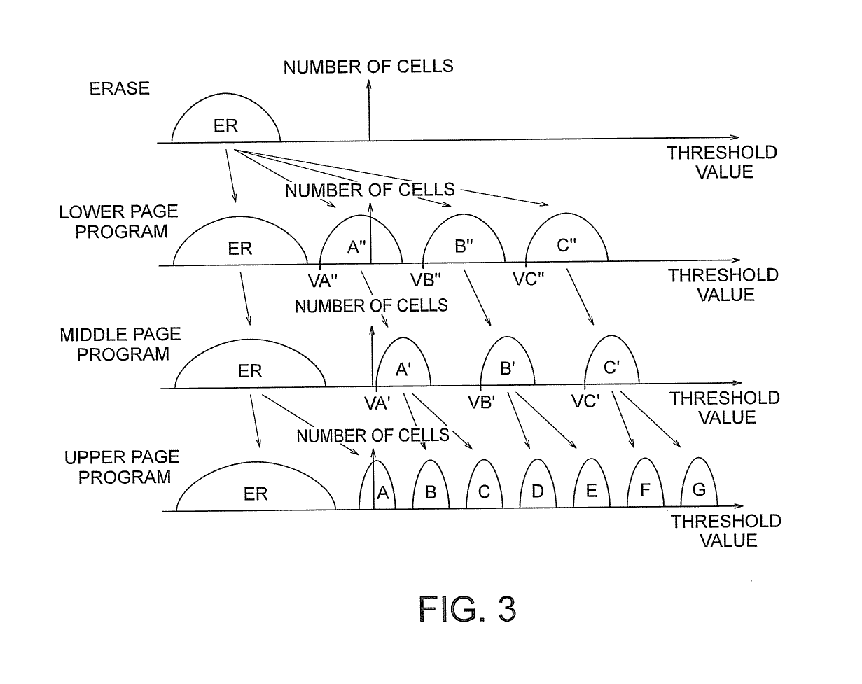

FIG. 3 illustrates another example of the method of writing data. In this example, an 8-value data storage method is executed in a non-volatile semiconductor storage device.

The 8-value data is defined by a negative threshold voltage distribution (erasing distribution) ER at a lowest level as the voltage level, and threshold voltage distributions A to G at voltage levels higher than the lowest level.

To write the 8-value data, first, all of the memory cells of the selection block are set to the lowest negative threshold voltage distribution ER.

Next, lower page writing (lower page program) is performed using verify voltages VA″, VB″, and VC″, and middle threshold voltage distributions A″, B″, and C″ having larger distribution ranges are obtained.

Following that, middle page writing (middle page program) is executed using verify voltages VA′, VB′, and VC′ from the distributions A″, B″, and C″, and middle threshold voltage distributions A′, B′, and C′ are obtained.

Following that, a writing operation is further executed from the threshold voltage distributions ER, A′, B′, and C′ obtained from the middle page data writing, and upper page writing (upper page data program) for obtaining final threshold voltage distributions ER, and A to G is performed. In the upper page writing, writing from the threshold voltage distribution ER to the threshold voltage distribution A, writing from the middle distribution A′ to the threshold voltage distribution B or C, writing from the middle distribution B′ to the threshold voltage distribution D or E, and writing from the middle distribution C′ to the threshold voltage distribution F or G are executed.

Next, a structure of the non-volatile semiconductor storage device of FIG. 1 will be described.

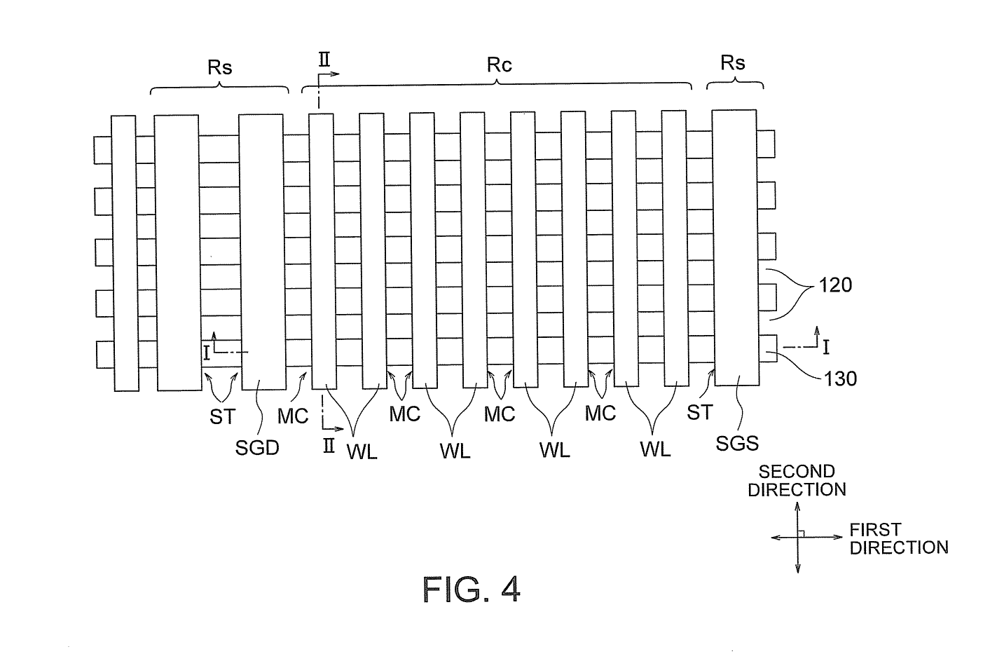

FIG. 4 is a plan view schematically illustrating a structure of the memory cell array 1 of the non-volatile semiconductor storage device of FIG. 1. In FIG. 4, an example in which one NAND string includes eight memory cells MC, which is different from FIG. 1, will be described for clarifying the description. In FIG. 4, a memory cell array region is indicated by Rc, and selection transistor regions are indicated by Rs.

As illustrated in FIG. 4, active regions 130 and element isolation insulating films (element isolation regions) 120 extend in a first direction (bit line direction). The active regions 130 and the element isolation insulating films 120 are alternately arranged in a second direction (word line direction). The first direction and the second direction are perpendicular to each other. A plurality of word lines WL extends in the second direction with predetermined intervals in the first direction. The selection gate lines SGD and SGS extending in the second direction are arranged to sandwich the word lines WL.

In the memory cell array region Rc, a memory cell MC is formed in a position where the active region 130 and the word line WL intersect with each other. In the selection transistor regions Rs, selection transistors ST are formed in a position where the active region 130 and the selection gate line SGS intersect with each other and in a position where the active region 130 and the selection gate line SGD intersect with each other.

Bit lines BL (illustration is omitted) are provided to overlap with the active regions 130. That is, a plurality of word lines WL intersects with a plurality of bit lines BL.

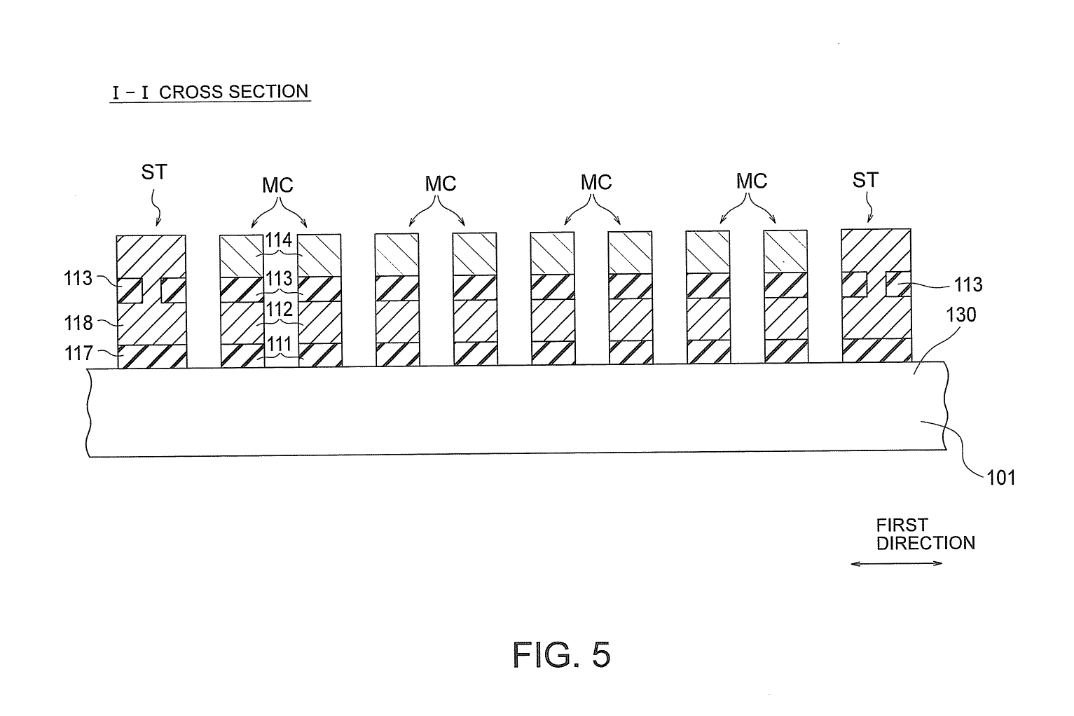

FIG. 5 illustrates a vertical section along the bit line BL of the plurality of memory cells MC and the selection transistors ST connected to one bit line BL in FIG. 4. That is, FIG. 5 is a cross sectional view along the I-I line (first direction) in FIG. 4.

As illustrated in FIG. 5, a plurality of memory cells MC and a plurality of selection transistors ST are provided on a semiconductor substrate 101 (active region 130). The active region 130 of the plurality of memory cells MC is integrally formed. That is, in the plurality of memory cells MC, current paths are connected in series.

The selection transistor ST includes a gate insulating film 117 formed on the semiconductor substrate 101, a gate electrode 118 formed on the gate insulating film 117, an IPD (inter poly-Si dielectric) film (second insulating film) 113 having an opening and formed in the gate electrode 118.

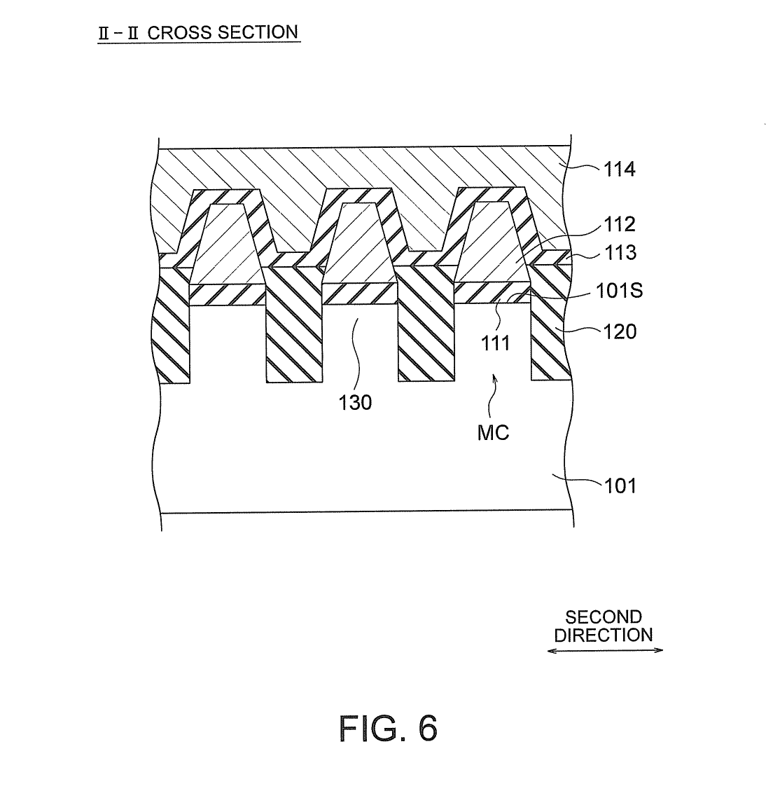

The structure of the memory cell MC will be described with reference to FIG. 6.

FIG. 6 illustrates a vertical section along the word line WL of the plurality of memory cells MC that shares one word line WL in FIG. 4. That is, FIG. 6 is a cross sectional view along the II-II line (second direction) in FIG. 4.

As illustrated in FIG. 6, a plurality of embedded-type element isolation insulating films 120 is formed on the semiconductor substrate 101 with predetermined intervals. A tunnel insulating film (first insulating film) 111, a floating gate 112, an IPD film 113, and a control gate (word line WL) 114 are layered in order on the semiconductor substrate 101 (active region 130) between the element isolation insulating films 120 to form the memory cell MC. The IPD film 113 is formed on the floating gate 112 and the element isolation insulating film 120. The control gate 114 is formed on the IPD film 113.

An upper surface of the floating gate 112 is higher than an upper surface of the element isolation insulating film 120. Therefore, the IPD film 113 has an uneven shape according to the surface shapes of the floating gate 112 and the element isolation insulating film 120 in the lower layers. Further, a lower surface of the control gate 114 has an uneven shape according to the surface shape of the IPD film 113 in the lower layer. The cross sectional shape of the floating gate 112 is a trapezoid.

As the tunnel insulating film 111, a silicon oxide film, a silicon oxynitride film, or a silicon nitride film is used, for example. As the floating gate 112, a polysilicon or a metal material such as TiN is used, for example. As the IPD film 113, a silicon oxide film, a silicon oxynitride film, a silicon nitride film, an Al₂O₃ film, an HfOₓ film, a TaOₓ film, or a La₂Oₓ film is used, for example. As the control gate 114, a polysilicon, a polysilicon doped with boron or phosphorus, metal such as TiN, TaN, W, Ni, or Co, or silicide thereof is used, for example. The element isolation insulating film 120 is a silicon oxide film, for example.

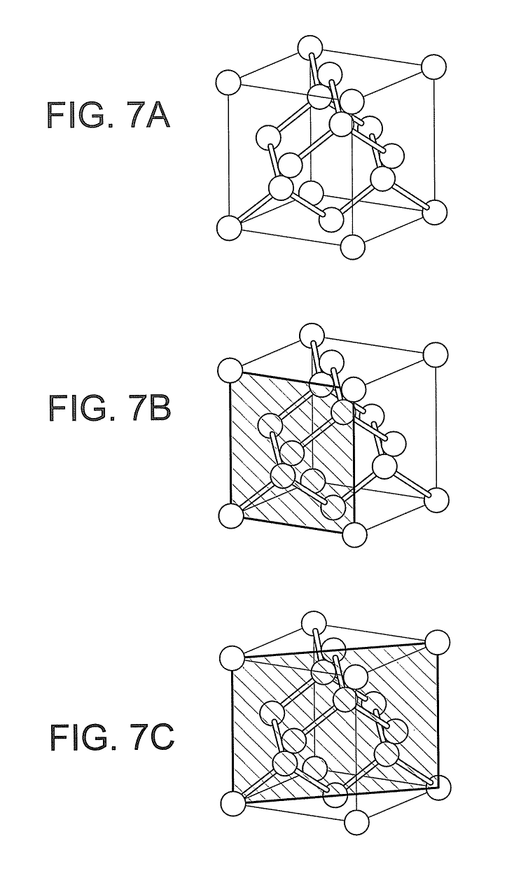

The semiconductor substrate 101 is a silicon substrate such as a single crystal silicon wafer. In the semiconductor substrate 101 (channel region (active region) 130) under the floating gate 112, a plane orientation (100) appears on a plane (channel side) being in contact with the element isolation insulating film 120. FIG. 7A illustrates a crystal structure of silicon. Further, the diagonal line part surrounded by the thick line of FIG. 7B indicates the (100) plane. For comparison, FIG. 7C illustrates a (110) surface. The diagonal line part surrounded by the thick line of FIG. 7C corresponds to the (110) surface.

In the present embodiment, the plane orientation appearing on the channel side is (100). Therefore, generation of a fixed charge in the interface between the channel region 130 and the element isolation insulating film 120 can be suppressed, compared with a case in which the plane orientation appearing on the channel side is (110).

Suppression of the generation of a fixed charge can suppress a decrease in neutral threshold voltage of the memory cell. Therefore, an increase in electric field applied to the tunnel insulating film 111 is prevented at retention of an electric charge in the floating gate 112, and the retention characteristic of data can be improved.

As described above, according to the non-volatile semiconductor storage device of the present embodiment, the retention characteristic of data is improved, and data writing can be accelerated.

In the present embodiment, it is favorable to suppress generation of the fixed voltage in a region having at least a depth of about an inversion layer formed in the active region 130 from a surface 101s of the semiconductor substrate 101. The depth of the inversion layer is about 20 nm, for example. More favorably, generation of the fixed charge may be suppressed in a region having a depth of about 50 nm from the surface 101s of the semiconductor substrate 101, more favorably, a depth of about 80 nm.

In other words, it is favorable that the element isolation insulating film 120 comes in contact with the (100) plane of the single crystal silicon wafer in a region from the surface 101s of the semiconductor substrate 101 to at least about a depth of an inversion layer (for example, a depth of 20 nm), favorably, about a depth of 50 nm, more favorably, about a depth of 80 nm. This is because the fixed charge existing from the surface 101s of the semiconductor substrate 101 to about the depth of the inversion layer has a substantial influence on the threshold voltage of the memory cell.

Therefore, when a groove for the element isolation insulating film 120 is processed in the semiconductor substrate 101, it is favorable to process a side surface of the groove to be perpendicular to the surface 101s of the semiconductor substrate 101 from the surface 101s of the semiconductor substrate 101 to at least about the depth of 20 nm, favorably, about the depth of 50 nm, more favorably, about the depth of 80 nm.

According to the present embodiment, the (100) plane is caused to appear on the channel side, whereby a leakage current can be suppressed in the memory cell MC.

Note that the cross sectional shape of the floating gate 112 is not limited to the example of FIG. 6, and may be another shape such as a bell shape.

### Second Embodiment

A second embodiment is different from the first embodiment in that a plane of an active region 130 being in contact with an element isolation insulating film 120 is a plane inclining from a (100) plane.

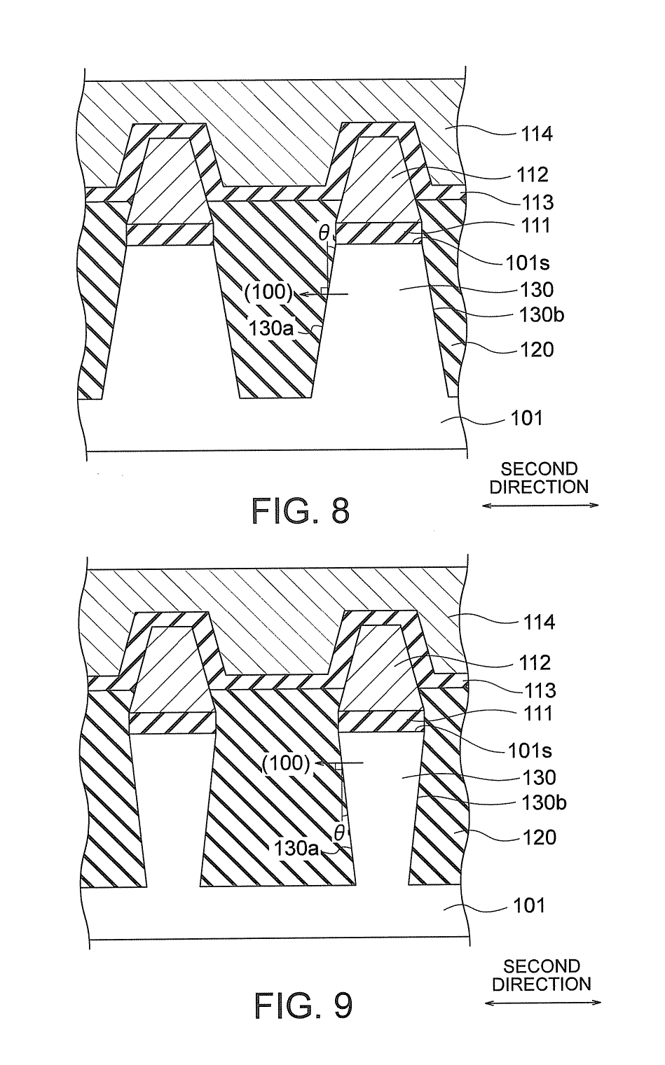

FIG. 8 is a vertical sectional view of a non-volatile semiconductor storage device according to the second embodiment. FIG. 8 corresponds to FIG. 6. In FIG. 8, configuration parts common to FIG. 6 are denoted with the same reference signs, and hereinafter, different points will be mainly described.

In the present embodiment, planes 130a and 130b of the active region 130 being in contact with the element isolation insulating film 120 are planes inclining from the (100) plane by an inclination angle θ of 5° or less. In the example of FIG. 8, a normal direction of the (100) plane is equal to a second direction. In this vertical section, a width of the active region 130 in the second direction becomes larger as being away from a surface 101s of a semiconductor substrate 101. That is, the planes 130a and 130b of the active region 130 being in contact with the element isolation insulating film 120 incline with respect to the normal line of the surface 101s of the semiconductor substrate 101 by the inclination angle θ of 5° or less.

A plane inclining from the (100) plane of the semiconductor substrate 101 by the inclination angle of 5° or less indicates physical properties nearly equivalent to that of the (100) plane because surface roughness is nearly equal to that of the (100) plane. Therefore, similarly to the first embodiment, generation of a fixed charge in an interface between the channel region 130 and the element isolation insulating film 120 can be suppressed.

In this example, when a groove for the element isolation insulating film 120 is processed in the semiconductor substrate 101, side surfaces (planes 130a and 130b) of the groove may not be processed to be perpendicular to the substrate surface 101s. Therefore, the non-volatile semiconductor storage device according to the second embodiment can be more easily manufactured than that of the first embodiment.

FIG. 9 is a vertical sectional view of another non-volatile semiconductor storage device according to the second embodiment. FIG. 9 corresponds to FIG. 8. In the vertical section of FIG. 9, the width of the active region 130 in the second direction becomes smaller as being away from the surface 101s of the semiconductor substrate 101. In this example, the planes 130a and 130b of the active region 130 being in contact with the element isolation insulating film 120 incline with respect to the normal line of the surface 101s of the semiconductor substrate by an inclination angle θ of 5° or less.

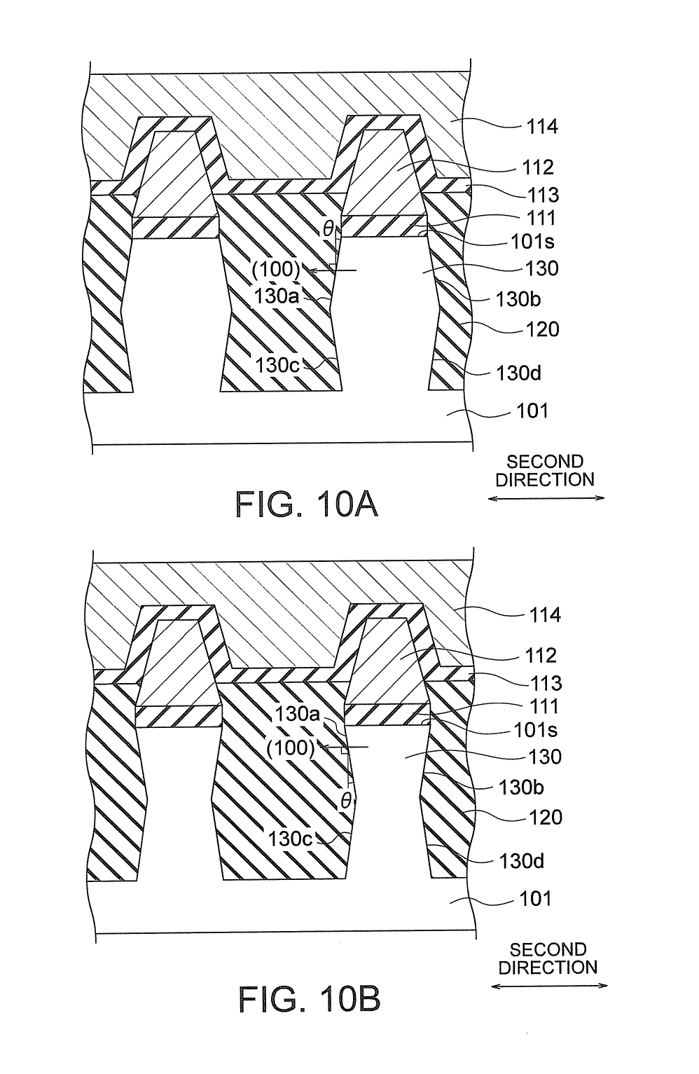

FIGS. 10A and 10B are vertical sectional views of other non-volatile semiconductor storage devices according to the second embodiment. FIGS. 10A and 10B correspond to FIG. 8. In the vertical section of FIG. 10A, the width of the active region 130 in the second direction becomes smaller after becoming larger as being away from the surface 101s of the semiconductor substrate 101. The width of the active region 130 in the second direction in the vertical section of FIG. 10B becomes larger after becoming smaller as being away from the surface 101s of the semiconductor substrate 101. In these examples, planes 130a, 130b, 130c, and 130d of the active region 130 being in contact with the element isolation insulating film 120 incline with respect to the normal line of the surface 101s of the semiconductor substrate by the inclination angle θ of 5° or less.

According to the non-volatile semiconductor storage devices of FIGS. 9, 10A and 10B, similar effects to the first embodiment can be obtained.

Note that the cross sectional shape of the active region 130 is not limited to the examples of FIGS. 8 to 10A and 10B as long as the plane of the active region 130 being in contact with the element isolation insulating film 120 is a plane inclining from the (100) plane by the inclination angle of 5° or less. The active region 130 may have a larger number of planes than the illustrated examples, and the inclination angles of the planes may be different from each other. The cross sectional shape of the active region 130 may not be symmetrical to the second direction.

### Third Embodiment

A third embodiment is different from the first embodiment in that a plane of an active region 130 being in contact with an element isolation insulating film 120 inclines with respect to a first direction.

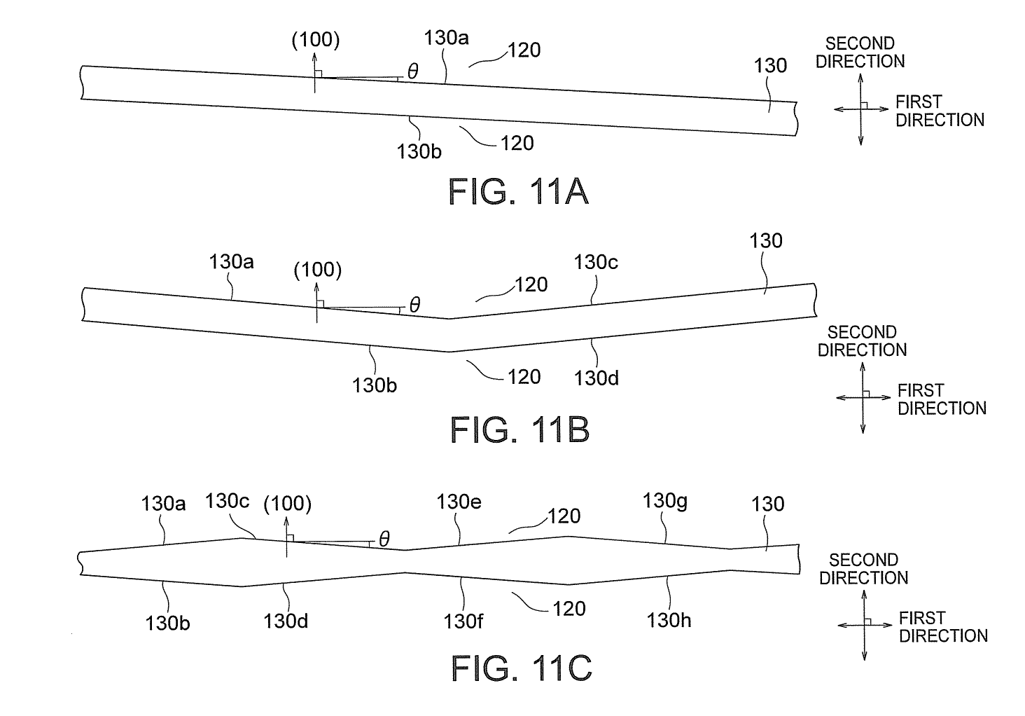

FIG. 11A is a top view illustrating the active region 130 of a non-volatile semiconductor storage device according to the third embodiment. While FIG. 11A corresponds to FIG. 4, only one active region 130 shared by a plurality of memory cells MC is illustrated and illustration of other configurations is omitted, for clarification of description.

In the present embodiment, planes 130a and 130b of the active region 130 being in contact with the element isolation insulating film 120 are planes inclining from a (100) plane by an inclination angle θ of 5° or less. In the example of FIG. 11A, a normal direction of the (100) plane is perpendicular to the first direction, and is equal to a second direction. The two planes 130a and 130b of the active region 130 being in contact with the element isolation insulating film 120 incline with respect to the first direction by the inclination angle θ of 5° or less. The two planes 130a and 130b are formed to be nearly parallel with each other. The active region 130 extends in a direction inclining with respect to the first direction, with nearly the same width.

FIG. 11B is a top view illustrating the active region 130 of another non-volatile semiconductor storage device according to the third embodiment.

In this example, planes 130a, 130b, 130c, and 130d of the active region 130 being in contact with the element isolation insulating film 120 incline with respect to the first direction by the inclination angle θ of 5° or less. The active region 130 bends in a dogleg shape manner and extends in the first direction with nearly the same width. The two planes 130a and 130b facing each other are formed to be nearly parallel with each other, and the two planes 130c and 130d facing each other are formed to be nearly parallel with each other.

FIG. 11C is a top view illustrating the active region 130 of still another non-volatile semiconductor storage device according to the third Embodiment.

In this example, planes 130a, 130c, 130e, and 130g of the active region 130 being in contact with the element isolation insulating film 120 are formed in a zigzag manner as viewed from above. Similarly, planes 130b, 130d, 130f, and 130h of the active region 130 being in contact with the element isolation insulating film 120 are formed in a zigzag manner. The planes 130a to 130h of the active region 130 being in contact with the element isolation insulating film 120 incline with respect to the first direction by the inclination angle θ of 5° or less. Accordingly, the active region 130 extends in the first direction while repeatedly increasing/decreasing the width.

According to the present embodiment, similar effects to the first embodiment can be obtained.

Note that the upper surface shape of the active region 130 is not limited to the examples of FIGS. 11A to 11C as long as the plane of the active region 130 being in contact with the element isolation insulating film 120 is a plane inclining from the (100) plane by the inclination angle of 5° or less. The active region 130 may have a larger number of planes than the illustrated examples, and the inclination angles of the planes may be different from each other. In FIG. 11C, the upper surface shape of the active region 130 may not be symmetrical to the second direction.

Further, the third embodiment may be combined with the second embodiment.

### Fourth Embodiment

A fourth embodiment is different from the first embodiment in that a lower part of an active region 130 is large.

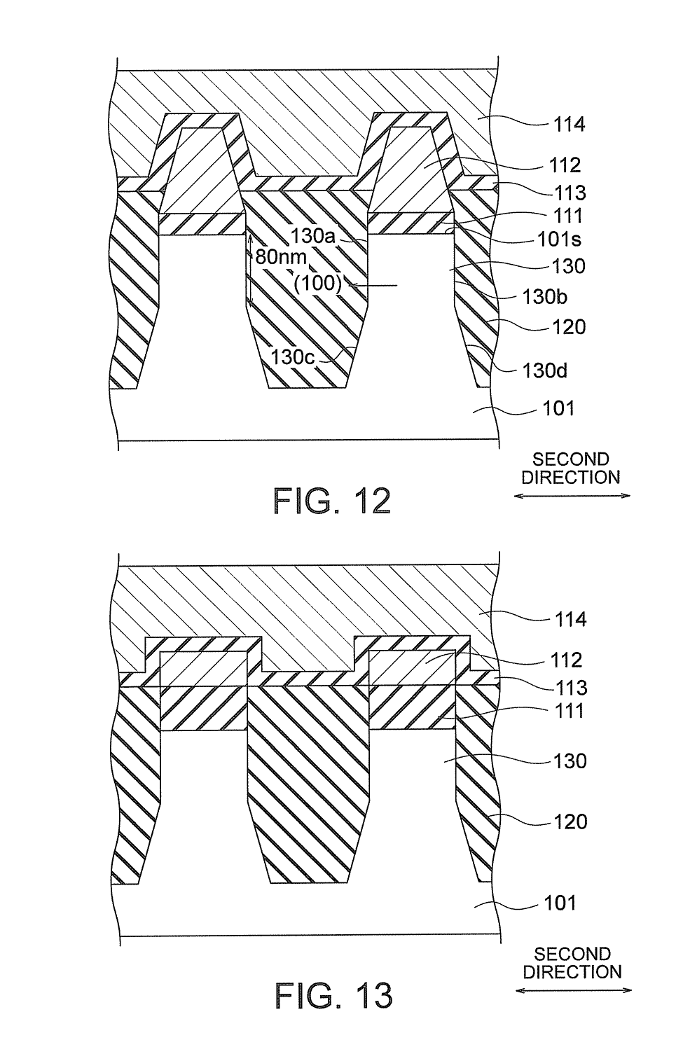

FIG. 12 is a vertical sectional view of a non-volatile semiconductor storage device according to the fourth embodiment. FIG. 12 corresponds to FIG. 6. In FIG. 12, configuration parts common to FIG. 6 are denoted with the same reference signs, and different points will be hereinafter mainly described.

As illustrated in FIG. 12, an element isolation insulating film 120 comes in contact with a (100) plane of a silicon substrate 101 in a region having a depth of about 80 nm from a surface 101s of the semiconductor substrate 101. That is, in the region, planes 130a and 130b of an active region 130 being in contact with the element isolation insulating film 120 are perpendicular to the surface 101s of the silicon substrate 101.

Further, in the vertical section, a width of the active region 130 in a second direction in a region deeper than a depth of about 80 nm from the surface 101s of the semiconductor substrate 101 becomes larger as being away from the surface 101s of the semiconductor substrate. Planes 130c and 130d of the active region 130 being in contact with the element isolation insulating film 120 in a region deeper than a depth of about 80 nm from the surface 101s of the silicon substrate 101 is planes inclining from the (100) plane of the semiconductor substrate 101 by an angle larger than 5°.

As described in the first embodiment, generation of a fixed charge may not be suppressed in the region deeper than the depth of about 80 nm from the surface 101s of the semiconductor substrate 101. Therefore, the planes 130c and 130d of the active region 130 being in contact with the element isolation insulating film 120 in this region may not be planes equivalent to the (100) plane.

According to the present embodiment, the strength of the active region 130 can be improved, in addition to the effects of the first embodiment. That is, for example, when a groove for the element isolation insulating film 120 is processed in the semiconductor substrate 101, the active region 130 can be prevented from falling down because the lower part of the active region 130 is large. Therefore, the non-volatile semiconductor storage device according to the present embodiment can be easily manufactured and reliability can be improved.

Note that, as described in the first embodiment, the width of the active region 130 in the second direction in a region deeper than about a depth of an inversion layer from the surface 101s of the semiconductor substrate 101 (for example, a depth of 20 nm), or in a region deeper than about 50 nm may become larger as being away from the surface 101s of the semiconductor substrate 101.

Note that the fourth embodiment may be combined with at least any of the second and the third embodiments.

### Fifth Embodiment

A fifth embodiment is different from the fourth embodiment in that the cross sectional shape of a floating gate 112 is a rectangle.

FIG. 13 is a vertical sectional view of a non-volatile semiconductor storage device according to the fifth embodiment. In FIG. 13, configuration parts common to FIG. 12 are denoted with the same reference signs, and different points will be hereinafter mainly described.

As illustrated in FIG. 13, the vertical sectional shape of the floating gate 112 is a rectangle. A height of a lower surface of the floating gate 112 is equal to a height of an upper surface of an element isolation insulating film 120 and a height of an upper surface of a tunnel insulating film 111.

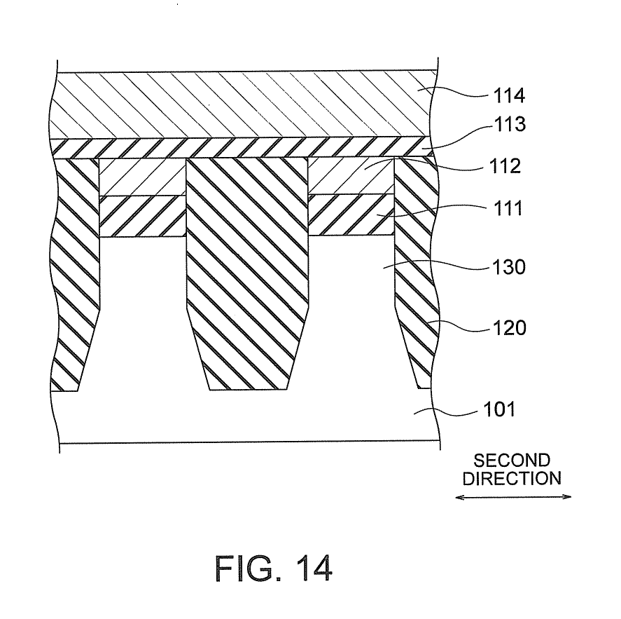

FIG. 14 is a vertical sectional view of another non-volatile semiconductor storage device according to the fifth embodiment. As illustrated in FIG. 14, the height of the upper surface of the floating gate 112 is equal to the height of the upper surface of the element isolation insulating film 120. As a result, an IPD film 113 and a control gate 114 are even.

In the fifth embodiment, the same effects as the fourth embodiment can be obtained.

The fifth embodiment may be combined with at least any of the first to the third embodiments.

Note that, in the first to the fifth embodiments, a floating gate-type memory cell MC has been described. However, similar effects can be obtained even if an electric charge trap-type memory cell is used instead of the floating gate-type memory cell MC. The electric charge trap-type memory cell may be, for example, a MONOS-type memory cell. The MONOS-type memory cell includes a silicon substrate including an active region isolated by an element isolation insulating film, a tunnel insulating film (first insulating film) formed on the active region, a silicon nitride film (charge accumulation layer) formed on the tunnel insulating film, a block insulating film (second insulating film) formed on the silicon nitride film, and a control gate formed on the block insulating film.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A non-volatile semiconductor storage device comprising:
a silicon substrate comprising an active region isolated by an element isolation insulating film;
a first insulating film formed on the active region;
a charge accumulation layer formed on the first insulating film;
a second insulating film formed on the charge accumulation layer; and
a control gate formed on the second insulating film,
wherein a plane of the active region being in contact with the element isolation insulating film is a (100) plane or a plane inclining from the (100) plane by an inclination angle of 5° or less.

2. The non-volatile semiconductor storage device of claim 1,
wherein the element isolation insulating film comes in contact with the (100) plane of the silicon substrate or the plane inclining from the (100) plane by an inclination angle of 5° or less, in a region having a depth of an inversion layer formed in the active region from a surface of the silicon substrate.

3. The non-volatile semiconductor storage device of claim 1,
wherein the element isolation insulating film comes in contact with the (100) plane of the silicon substrate or the plane inclining from the (100) plane by an inclination angle of 5° or less, in a region having a depth of 50 nm from a surface of the silicon substrate.

4. The non-volatile semiconductor storage device of claim 1,
wherein the element isolation insulating film comes in contact with the (100) plane of the silicon substrate or the plane inclining from the (100) plane by an inclination angle of 5° or less, in a region having a depth of 80 nm from a surface of the silicon substrate.

5. The non-volatile semiconductor storage device of claim 1,
wherein the active region extends in a first direction, and
in a vertical section along a second direction perpendicular to the first direction, a width of the active region in the second direction becomes larger as being away from a surface of the semiconductor substrate.

6. The non-volatile semiconductor storage device of claim 1,
wherein the active region extends in a first direction, and
in a vertical section along a second direction perpendicular to the first direction, a width of the active region in the second direction becomes smaller as being away from a surface of the semiconductor substrate.

7. The non-volatile semiconductor storage device of claim 1, comprising:
a plurality of memory cells arranged in a first direction,
wherein each of the memory cells comprises the active region, the first insulating film, the charge accumulation layer, the second insulating film, and the control gate,
the active region of the plurality of memory cells is integrally formed,
a normal direction of the (100) plane of the silicon substrate is perpendicular to the first direction, and
the plane of the active region being in contact with the element isolation insulating film inclines with respect to the first direction by an inclination angle of 5° or less.

8. The non-volatile semiconductor storage device of claim 1, comprising:
a plurality of memory cells arranged in a first direction,
wherein each of the memory cells comprises the active region, the first insulating film, the charge accumulation layer, the second insulating film, and the control gate,
the active region of the plurality of memory cells is integrally formed,
a normal direction of the (100) plane of the silicon substrate is perpendicular to the first direction, and
the plane of the active region being in contact with the element isolation insulating film is formed in a zigzag manner as viewed from above, and
each plane of the active region being in contact with the element isolation insulating film inclines with respect to the first direction by an inclination angle of 5° or less.

9. The non-volatile semiconductor storage device of claim 4,
wherein the active region extends in a first direction,
in a vertical section along a second direction perpendicular to the first direction, a width of the active region in the second direction in a region deeper than the depth of 80 nm from the surface of the silicon substrate becomes larger as being away from a surface of the semiconductor substrate, and
a plane of the active region being in contact with the element isolation insulating film in a region deeper than the depth of 80 nm from the surface of the silicon substrate is a plane inclining from the (100) plane of the semiconductor substrate by an inclination angle of more than 5°.
